(19) United States
(12) Patent Application Publication
(10) Pub. No.: US 2025/0027194 A1
(43) Pub. Date: Jan. 23, 2025

(54) Methods for Fabricating Surface-enhanced Raman Spectroscopy Substrates

(71) Applicants: Yimin Hu, Clarksville, MD (US); Feng Niu, Arlington Heights, IL (US); Wei Lu, Great Falls, VA (US)

(72) Inventors: Yimin Hu, Clarksville, MD (US); Feng Niu, Arlington Heights, IL (US); Wei Lu, Great Falls, VA (US)

(73) Assignee: Raytum Photonics LLC., Sterling, VA (US)

(21) Appl. No.: 18/224,645

(22) Filed: Jul. 21, 2023

(51) Int. Cl. C23C 16/455

(52) U.S. Cl. CPC C23C 16/45525

(57) ABSTRACT

This invention provides a process or method of fabricating low cost, large area 3D porous filter SERS substrates all by atomic layer deposition which includes first depositing a chemical wetting layer to improve surface wetness for subsequent coating deposition, then a high refractive index dielectric layer for tuning LSPR wavelength for a desired application, and subsequently depositing noble metal nanoparticles such as Ag or Au, etc. on the 3D porous filers to form strong LSPR signals as the hotspots for SERS enhancements, lastly an environmental protection or passivation layer may be needed to prolong shelf life of such 3D SERS substrates.

### ACKNOWLEDGMENT OF GOVERNMENT SUPPORT

This invention was made with government support under Contract No. W911SR22C0025 awarded by the U.S. Department of Defense. The government has certain rights in the invention.

### FIELD OF THE INVENTION

The present invention relates to a novel process of fabricating low cost, large area high enhancement surface-enhanced Raman spectroscopy (SERS) substrates by all atomic layer deposition (ALD) on cheap commercial 3D porous filter papers.

### BACKGROUND

Surface enhanced Raman scattering (SERS) has emerged as a promising spectroscopic tool for ultrasensitive trace detection of target molecules in the vicinity of noble metal nanostructured surface. SERS active substrates coated by noble metal nanostructured surfaces like Gold (Au), Ag (sliver) can enhance the sensitivity of Raman spectroscopy due to their unique localized surface plasmonic resonance (LSPR) properties. Enhancement factors (EF) as high as 10⁶ (theoretically up to 10¹⁰-10¹¹) has been achieved with such substrates by readily tuning the optical properties of noble metal nanostructured surfaces through engineering of their shape, size, orientation, and architecture, even allowing for single molecule SERS detection in certain specific cases. In order to achieve very high sensitivities with SERS over more than a single random location (i.e., isolated hot spot), it is necessary to take advantage of the localized electric field enhancement associated of the noble metal nanostructures such as nanoparticles, nanorods, nanowires, nanotubes, core-shell nanostructures, etc. by tuning the gaps to create a high density of isolated “hot spots”. In addition, to optimize EFs of the SERS substrates over an extended area, the ability to produce a substrate that is environmentally stable, capable of being recycled, conformal to the analysis surface of interest and cost-effectiveness are all critical for the development a truly field deployable SERS detection system.

Since the discovery of SERS, many methods have been developed to fabricate SERS substrates with most of them falling into three categories: noble metal nanoparticles (NMNPs) by colloidal chemistry, nano-patterned surfaces, physical and chemical vapor deposition (PVD/CVD) or a combination of them. The most widely used metal nanoparticles display a simple spherical morphology, at the expense of higher SERS signal enhancement due to their rounded symmetry. Aggregated colloidal nano-patterned surfaces feature low cost while often exhibiting very strong enhancement due to a three-dimensional (3D) distribution of plasmonic hotspots. However, since colloidal aggregation is a dynamic process, SERS spectra must be recorded over time, resulting in an averaging of the random hot spots and SERS enhancement, thereby reducing the maximum achievable signal in order to achieve reproducibility.

Several micro-nano patterning techniques such as lithography, ion beam and focused ion beam, etc. have been used to design very effective large area patterned SERS active substrates of a 2D planar array nature. These include the fabrication of diverse NMNPs with a high density (on a single 2D plane) of hot spots. Although large SERS enhancements have been achieved using these techniques, fabrication of such substrates is limited in the probing amount and often involve complicated (sometimes irreproducible) fabrication steps with high production cost.

PVD techniques such as ion beam sputtering, reactive magnetron sputtering, electron beam and thermal evaporators with ion assistance, etc. are traditional, well established coating techniques readily available. However, they all have been subject to intrinsic drawbacks of poor conformality in coating on 3D substrates (capable only in sight of light), poor large area uniformity, difficulty in precise nanometer thickness control and high cost associated with high or ultra-high vacuum technology and thickness monitoring tools.

All above techniques have limitations to coating hotspots directly inside 3D SERS substrates. So, on one hand there is high demand for super-enhancement, and ultra-sensitivity SERS substrates, on the other hand it is still challenging due to lack of stability, reproducibility, and reusability for such SERS active substrates to enter the realms of real, practical applications. There is a need for new methods of fabricating SERS substrates to address the problems of prior arts.

### SUMMARY OF THE INVENTION

Disclosed herein are representative embodiments of methods and apparatus to fabricate super enhancement, ultra-sensitive, SERS active substrates using Atomic Layer Deposition (ALD) as shown in FIG. 1. ALD has made dramatic achievements in various fields such as semiconductor development, catalysis, energy and environmental applications. ALD is a cyclic process carried out by dividing a conventional chemical vapor deposition (CVD) process into an iterated sequence of self-saturating deposition cycles. Unlike CVD where the reacting gases are mixed in the process chamber and continuously react to form a film, ALD reacting gases are delivered separately to react with the surface instead of with each other. Each reaction is self-terminating, depositing a single layer at a time, independent of gas flow distribution or gas transport into substrate features and forming super conformal, continuous coatings in low process temperatures. ALD has been able to provide a critical need for an important technology at a time when no other methods could meet the need. For example, non-planar devices impose geometrical challenges for materials integration. The required conformal deposition necessitates layer-by-layer fabrication that can only be delivered by ALD.

Due to its unique characteristics of super conformity, large area uniformity, easy layer thickness/composition control with precision in atomic scale, low cost and easy scale-up, if designed rationally it is an excellent technique for the bottom-up fabrication of nano-scaled materials and devices. ALD process has also been extensively investigated for the fabrication of SERS active substrates including Au or Ag NPs, ultra-thin films, conformal coatings of 3D scaffolds, high aspect ratio NMNs, core-shell nanostructures, tunable nanogaps and high-density hot spots on nanostructured scaffold, etc. Furthermore, ALD ultra-thin coating with novel functional dielectric materials provides protection to the NMNs against aggregation, oxidation, and surface contaminations. ALD Al₂O₃, TiO₂, etc. have been proven very effective as spacer/passivation layers for multi-layer enhanced SERS substrates. In addition, ALD ultra-thin coating maintains their LSPR properties and hot spot intensity for further use. This is important from the point of view that agglomeration of NMNs (immobilized on a substrate) from colloidal sample leads to the damping of their optical properties. Therefore, ultra-thin surface coatings of these MNS nanostructures using adequate materials allow them to retain their desired/tailored functional properties. ALD ultrathin coatings help to improve the optical properties and chemical stability of NMNs based SERS active substrates. Therefore, ALD is a very promising technique for the rational design of SERS substrates as compared to other existing techniques (e.g., colloidal chemistry, nano-patterning, and PVD). Besides, ALD also has great potential for the fabrication of large area, low-cost nanostructured substrates for commercial SERS applications.

Direct deposition of metallic NPs (Au, Ag, etc.) by ALD in reliable (Au, Ag) metalorganic precursor developments and truly ALD self-limiting process have not been demonstrated by ALD until more recently. The SERS effect for Au NPs produced by ALD has also been reported. However, no signature LSPR peaks of Au NPs were proven thus if it is real SERS effect still questionable and no specific SERS substrates were mentioned. In our invention we have demonstrated for the first time the presence of the signature LSPR peaks from Ag NPs by ALD and the presence of the SERS enhancement effect fabricated on those cheap commercial 3D porous filters. This invention demonstrated that it is not only possible for ALD process or method to generate Au or Ag nanoparticles of controllable size at many depths on the various truly 3D substrate supports such as filter paper, silica fibers, etc., thus provide massive potential surface area for easy access for various analytes and high sensitivity, but it is also possible to generate multiple controlled size metal nanoparticles simultaneously thus potentially for detecting wavelength range SERS signals.

Prior arts on these substrates were limited to ALD conformal and contiguous coatings of dielectrics on MNS as spacer layers and surface passivation layers for assisting and improving SERS substrate performance. The method disclosed herein can dramatically increase volume coverage of metallic NPs due to ALD's super-conformity. It can also maximize EFs and sensitivity of metallic NPs, which are usually limited in traditional PVD coating techniques due to shadow effects. With the stronger SERS signal from the application of the proposed geometry, it should be easy to generate SERS enhancements of at least 10⁵-10⁶ over an extended large area (for non-resonant enhanced analytes) with stable enhancements as great as 10¹² possible. In addition, this method can significantly reduce the complexity and thus cost by fabricating SERS substrates in a single ALD coating process.

### BRIEF DESCRIPTION OF THE DRAWINGS

FIG. 1 Illustration of the concept and the method of fabricating SERS substrate by all ALD.

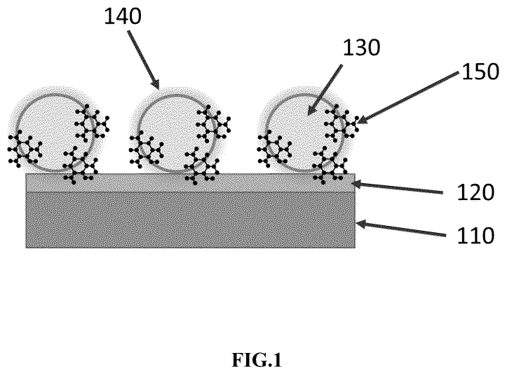

FIG. 2 Flow chart of the SERS substrate fabrication procedures.

FIG. 3 SEM micrographs of Ag NP morphology on Si with different cycles.

FIG. 4 SEM image of 3000 cycle Ag coated sample on Si; bottom left and right: EDS spectrum on two different areas showing Ag rich NPs.

FIG. 5. Measured reflectivity of 500-1500 cycle Ag NMNPs coated on flat frosted glass substrates.

FIG. 6 shows modelling results of Ag NMNPs with different surface coverage (10%-70%) on the same flat glass substrate.

FIG. 7. A flow through coating fixture developed for enhancing Ag NMNPs deposition deep inside filter papers.

FIG. 8. SEM cross sectional micrograph from 10000 cycle Ag coated glass fiber filter paper.

FIG. 9. SERS of pyridine passing through 1500 cycle Ag NMNPs coated glass fiber filters.

### DETAILED DESCRIPTION

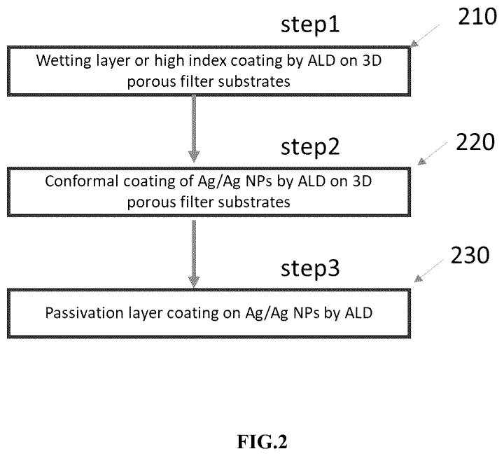

Disclosed herein FIG. 2, this process or method of fabricating SERS substrates consists of following steps:

Step1 (210): a conformal thin (120) or multi-layer of SiO₂, Al₂O₃, TiO₂ or other dielectrics will firstly be deposited around the 3D fabric network of the filter membranes (110). It serves as a wetting layer to alter the surface property of polymer or dielectric fibers to facilitate the adhesion of subsequent metal layer deposition. For example, a native polymer surface normally shows strong hydrophobic property, which is not ideal for forming continuous ALD films. These wetting layers also serve as a dielectric medium among metallic NPs to tune LSPR peaks. The LSPR wavelength and intensity which are dependent on surrounding/supporting dielectric materials of NMNPs can be precisely tuned by ALD process to maximize EFs and sensitivity of target analytes. Note that it is also possible to generate multiple LSPS peaks at different wavelengths to detect multiple chemicals on the same SERS substrate to reduce cost and improve efficiency.

Step2 (220): NMNPs deposition on and in the porous fiber filter papers by ALD (130). The key challenge is to tune Au/Ag NMNPs by ALD process to maximize hotspots density, coverage, NP sizes both on surface and depth of the porous filters.

Step3 (230): Immediately after step 2 without breaking vacuum, a sub-nanometer super thin Al₂O₃, TiO₂ or other dielectric oxides (140) may be deposited on Au/Ag NMNPs to isolate Au/Ag NMNPs from air. This step not only maximizes EFs, but also prevents well known surface tarnishing effects of Au and Ag and thus extend shelf-life of the substrates that could be employed months or even longer after fabrication.

We use preferably Ag NMNPs to fabricate the SERS. Typically, Ag will outperform comparable Au substrates by about two orders of magnitude in enhancement. Silver precursors have also significant cost advantage compared to Au ones.

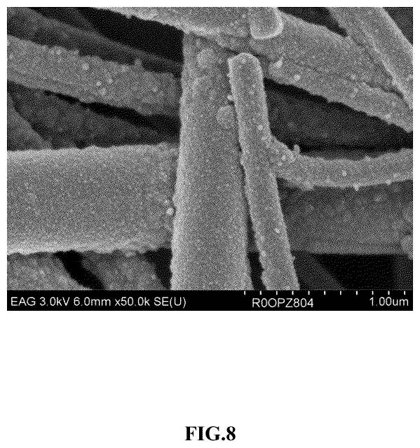

Though Ag LSPA peaks could be short lived, and the enhancement will decay significantly within hours of fabrication because of oxidation and rapid degradation of SERS enhancement, one of the uniqueness of an ALD process for a rational design of SERS substrates is it is possible to apply sub-nanometer super thin passivation layer like Al₂O₃, or TiO₂ to prevent silver nanoparticle surface from oxidation/tarnishing thus prevent the enhancement decay eventually as proved in literatures. For example, using a few cycles of Al₂O₃, silver nanorods wrapped with ultrathin Al₂O₃ layers exhibiting excellent SERS sensitivity and outstanding SERS stability with significantly extended shelf-life time up to 50 days still with no sign of degradation in Raman intensity even though SERS sensitivity got sacrificed after Al₂O₃ coating by 30-50% dependent on cycle numbers (1-5). Most recent study revealed that Ag dendrites coated by 10-cycle ZnO exhibit the improved SERS sensitivity compared to the pristine Ag dendrites. The theoretical simulations also demonstrate that ultrathin ZnO coating can promote the plasmonic coupling in Ag nanogaps as shown in FIG. 8. More importantly, this SERS substrate also shows excellent thermal stability at elevated temperature of 200° C. Therefore, both SERS sensitivity and thermal stability of Ag dendrites can be enhanced via ALD surface protection.

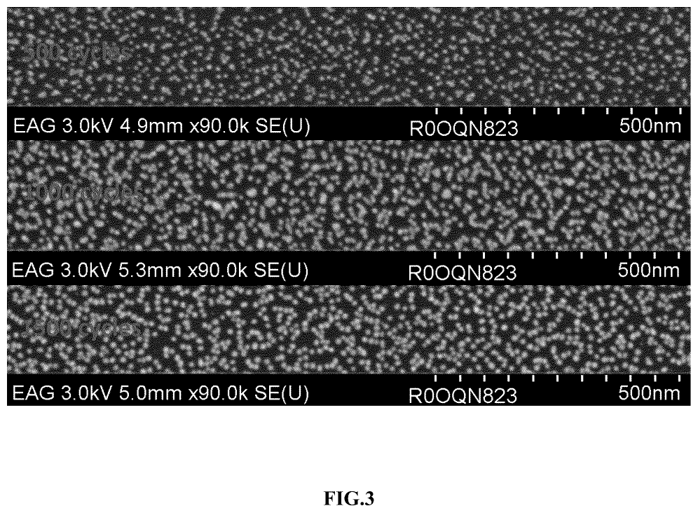

FIG. 3 shows one example of ALD Ag process to make SERS substrate. Evolution of morphology of isolated Ag NPs from 500, 1000 to 1500 cycles with estimated average sizes increase from 3-5, 5-7, to 7-9 nm and surface coverage from 15-25%, 30-40%, to 50-60%. The particle sizes are uniform, and the size distribution is narrow. In addition, there is no obvious formation of Ag NP agglomerates and continuous films to achieve maximal hotspot density on surface due to fine controlling of cycle numbers. By fine tuning Ag nanostructures and controlling cycle numbers of ALD deposited Ag films, high density isolated Ag nanoparticles (NPs) with average sizes in 3-9 nm are obtained depending on the cycle numbers without formation of agglomerates and continuous Ag films.

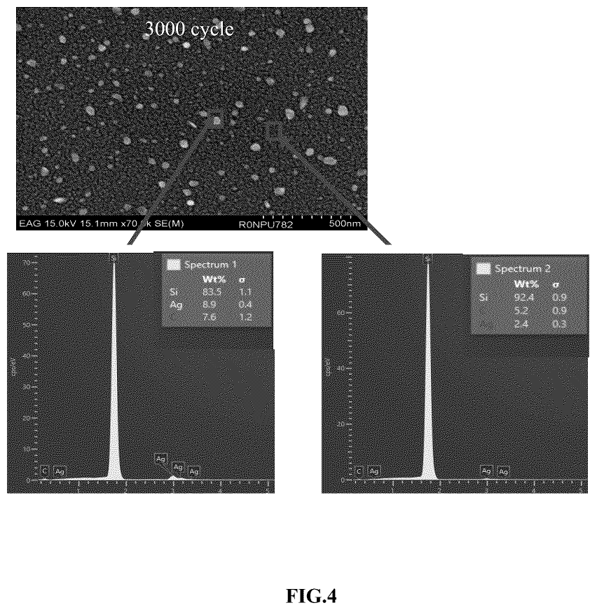

FIG. 4 shows X-ray dispersive spectrometry (EDX) from a 3000-cycle sample showing dominated Ag signals and low impurities besides Si substrate signals.

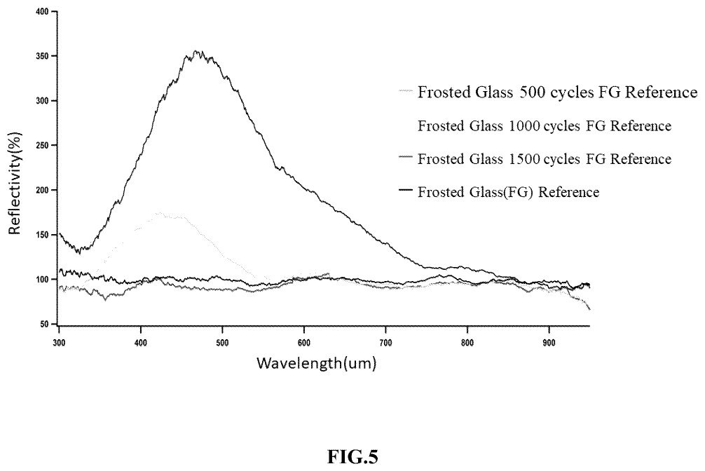

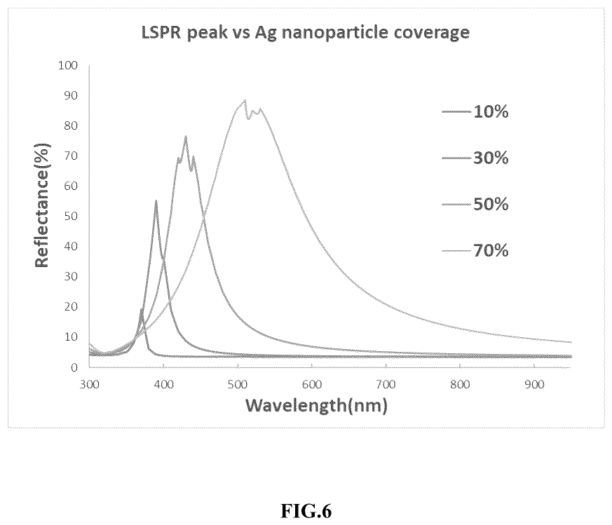

FIG. 5 shows measured reflectivity from the same Ag coatings as the above SEM micrographs with different cycle numbers. A broad LSPR peak between 400-500 nm is clearly present compared to an uncoated glass substrate with LSPR peak intensity and wavelength strongly dependent on the cycle number. For example, the 500-cycle sample shows a weak LSPR peak at 415 nm while the 1500 cycle sample shows a significantly stronger and also shifted LSPR peak at 480 nm. We demonstrated for the first time that strong LSPR peaks were observed from Ag NPs with the peak intensity and wavelength strongly dependent on the cycle numbers. Modelling based on the effective medium theory matches measured reflectivity well as shown in FIG. 6 and confirms that isolated, high density and high coverage Ag NPs dominate the LSPR peaks.

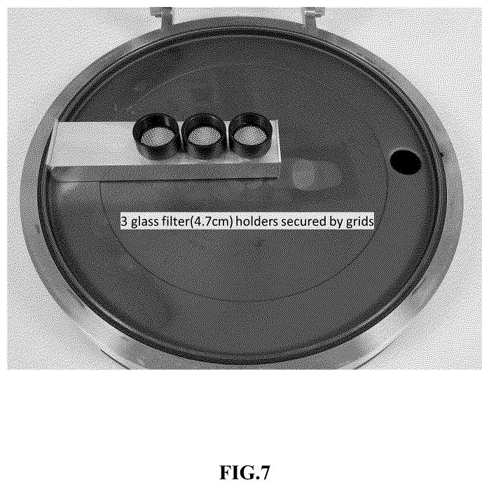

Another example of Ag ALD process over a flow-through glass fiber coating fixture is shown in FIG. 7. The ALD process can force all precursors to pass through porous fibers to coat Ag NMNPs deeper and more uniform thus to maximize hotspot density and volume in 3D direction which is critical to increase accessibility of biochemical analytes and SERS sensitivity. This may also help increase Ag precursor utilization mostly reacted inside the filter papers. The current fixture can coat three filter papers with 47 mm in diameter. However, each holder column can be expanded to accommodate multi-filters easily in Veeco S200 batch reactor in the future for volume production. This flow-through fixture is proven to enhance deep and uniform coating inside the 3D porous glass fiber filters and the fixture has been proven to work well as shown in FIG. 8 which clearly demonstrates unique and super-conformalty of Ag coated around glass fibers covering many layers of fibers along the depth direction inside 3D networks. Energy dispersive spectroscopy (EDS) confirms the NPs are Ag rich, most EDS peaks are associated with glass fiber substrates except P, F, B which are associated with Ag precursor (P, F) <1%.

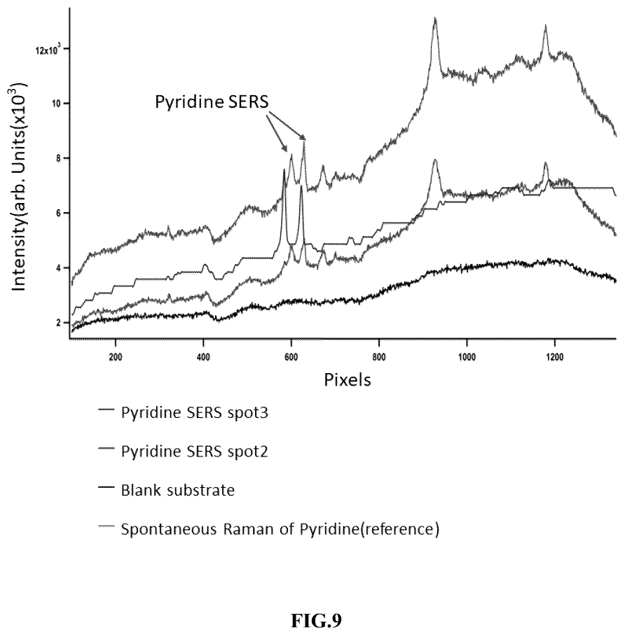

FIG. 9 shows measured SERS signals from Pyridine which are measurable and consistent over a few glass fibers (2.7 um in average pore size and 600 um in thickness) coated with 1500 cycle Ag. The pyridine spontaneous Raman spectrum provides a solid reference. The two strong peaks are from the pyridine reference. The spontaneous Raman spectrum is taken from pure pyridine solution with 1 W laser power, and the excitation laser wavelength is 514 nm. When pyridine solution passes the Ag coated glass fibers the two SERS pyridine spectra show shoulders as labelled and highlighted at the same position as the pyridine bands.

What are claimed are:

1. A process or method of fabricating SERS active substrates all by atomic layer deposition (ALD) on commercial glass filter paper substrates: comprising first depositing a continuous and conformal dielectric layer for tuning target wavelength of the localized surface plasmon resonance (LSPA) or as the chemical wetting/adhesion layer; secondly, depositing a conformal nanostructure wrapped around all 3 dimensional (3D) porous fibers in thickness direction all the way to form high density 3D isolated island-like nano-sized metallic particles and the nanostructure has to be tuned to show maximal intensity of LSPA peaks; immediately after the second step, a dielectric passivation layer of sub-nanometer in thickness to be deposited conformally on those nanoparticle surface to sustain long-shelf life of the SERS active substrates when exposed to air.

2. The process according to claim 1, wherein the nanoparticles are selected from Au, Ag, Cu, Pt, and other noble metals showing strong LSPA at different wavelength ranges such as UV, Visible and Near IR.

3. The process according to claim 1, the dielectric layers for tuning target wavelengths of the localized surface plasmon resonance (LSPA) are selected but not limited from TiO₂, HfO₂, ZrO2, Ta₂O₅ having a high refractive index >2.

4. The process according to claim 1, wherein the SERS base substrates include commercially available filter papers made of glass fibers with high aspect ratio (>50) of thickness vs pore size and any other similar substrate materials which are mechanically and chemically compatible with ALD process and have low SERS background signals.

5. The process according to claim 1, the noble metal nanoparticles are deposited using a thermal atomic layer deposition modified with a low pressure precursor boosting kit and a special flow-through coating fixture to ensure sufficient precursor vapor pressure, and to force all precursors to pass through porous fibers and uniformly coated on large area substrates.

6. The process according to claim 1, the chemical wetting/adhesion layer and the dielectric passivation layer are selected but not limited from Al₂O₃, SiO₂, ZnO, TiO₂.
